(19) United States
(12) Patent Application Publication
(10) Pub. No.: US 2006/0118834 A1
(43) Pub. Date: Jun. 8, 2006

(54) Semiconductor device and method of manufacturing the same

(76) Inventors: Hiroshi Ohta, Kawasaki (JP); Hiroyuki Uchiyama, Musashimurayama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/295,595

(22) Filed: Dec. 7, 2005

(30) Foreign Application Priority Data
Dec. 7, 2004 (JP) 2004-354007

(51) Int. Cl. H01L 29/80

(52) U.S. Cl. 257/275

(57) ABSTRACT

In a microwave integrated circuit, a capacitance element is connected to the input side of each active device to remove noise signals. These capacitance elements and the wires, etc. for them have prevented the miniaturization of the chip since they require large areas on the chip. Further, in the case of a semiconductor active device, particularly a field-effect transistor, the gate metal formed on the step portions of the mesa may break or the gate metal may come into contact with the active layer during the “mesa-type device separation” process, resulting in degradation in the characteristics. To overcome the above problems, the present invention provides a device configuration in which: the capacitance element is formed right under one terminal of the semiconductor device; and one of the two electrodes of the capacitance element is connected to the underside of the terminal. Further, the gate metal is coated on planar portions of the semiconductor device surface, and the semiconductor substrate and portions of the active layers other than those in the transistor active region are removed from the rear portion of the device.

### CLAIM OF PRIORITY

The present application claims priority from Japanese application JP 2004-354007 filed on Dec. 7, 2004, the content of which is hereby incorporated by reference into this application.

### BACKGROUND OF THE INVENTION

The present invention relates to semiconductor devices such as semiconductor active devices, microwave integrated circuits (MMICs), and power amplifier modules that contain a microwave integrated circuit, etc., and manufacturing methods therefor.

There has been a strong need to reduce the size of mobile communication systems such as cellular phones and hence minimize their components.

One of such components is the power amplifier MMIC, in which a capacitance element is connected to the input side of each internal semiconductor device to remove low frequency noise and thereby stabilize the operation of the device. Generally, the high-frequency input signal is input to the input side of the first-stage semiconductor device through its capacitance element, and output from the output side of the device. The signal output from the first-stage semiconductor device is input to the second-stage semiconductor device through its capacitance element and amplified therein before being output from the device. Conventionally, these capacitance elements are arranged horizontally on planar regions around the semiconductor devices. Each capacitance element is made up of: a signal input wire; an input electrode (or upper electrode) connected to the signal input wire; a dielectric film disposed right under the input electrode; an output electrode (or lower electrode) disposed right under the dielectric film; and an output wire connected to the output electrode. This means that it is necessary to reserve space for these components on the chip.

The “mesa-type device separation” method is typically used for device separation between the active regions in a semiconductor active device. This method separates the devices by removing active layers other than those in the active regions. However, particularly in the case of a field-effect transistor, since the gate electrode formed on the mesa need be extended out of the mesa region, gate metal must be coated on the step portions of the mesa.

On the other hand, in the field of common semiconductor devices, there are methods known in the art that arrange the components of a semiconductor device three-dimensionally in order to increase the integration density. Specifically, for example, some of these methods dispose the capacitance elements under transistors. See, for example, Japanese Patent Laid-Open No. 5-90491 and No. 2001-60664.

However, the above capacitance elements have prevented the miniaturization of the MMIC, since they require large areas on the chip.

### SUMMARY OF THE INVENTION

To solve the above problem, for example, the capacitance elements may be formed on the rear side of other devices disposed on the semiconductor chip, as described above. However, even in this case, it is necessary to arrange on the chip the wires, via holes (or through-holes), etc. for connecting between the semiconductor devices disposed on the top and back surfaces. When via holes are formed in a semiconductor substrate, its thickness is usually reduced to 30 μm-100 μm, taking into account the handling characteristics. That is, in this case, through-holes having a depth of 30 μm-100 μm are formed. Through-holes having such a depth must have a diameter of 30 μm-100 μm or more if a sufficient aspect ratio is to be ensured. This results in an increase in the required chip area.

Further, the above conventional methods have other problems. For example, in a semiconductor active device, particularly a field-effect transistor, the gate metal coated on the step portions of the mesa may break, or the gate metal may come into contact with the active layers exposed at sides of the mesa.

To solve the above problems, the present invention provides a microwave integrated circuit device configured such that: the capacitance element formed on the back surface of the chip for each internal semiconductor device is formed right under one terminal of the semiconductor device; and one of the two electrodes of the capacitance element is connected to the terminal on its underside (see FIGS. 6B and 6C).

According to another aspect of the present invention, the microwave integrated circuit device is further configured such that: the entire semiconductor substrate or at least the portions of the semiconductor substrate in the regions in which the semiconductor devices and the capacitance elements are formed have been removed; and the top and back surfaces are connected to each other by use of contact holes (or through-holes) having a diameter approximately equal to the thickness of the interlayer insulating film covering the top surface.

According to still another aspect of the present invention, the gate metal is coated on planar portions of the semiconductor surface, and the semiconductor substrate and active layers other than those in the transistor active regions are removed from the rear portion of the device. This avoids the problem of breakage of the gate metal on the mesa step portions during the “mesa-type device separation” process, as well as contact between the gate metal and the active layers.

The present invention facilitates the miniaturization of semiconductor chips. Furthermore, the present invention allows semiconductor active devices formed on a chip to be wired without any problem.

Other objects and advantages of the invention will become apparent from the following description of embodiments with reference to the accompanying drawings.

### BRIEF DESCRIPTION OF THE DRAWINGS

FIG. 1 is a cross-sectional view of an exemplary HBT in which the capacitance element is disposed under the base layer.

FIG. 2 is a cross-sectional view of an exemplary configuration of HBTs in which the capacitance element is disposed under the conductor layer connected to the collector layer.

FIG. 3 is a cross-sectional view of an exemplary HBT in which the capacitance element is disposed under the collector layer.

FIG. 4 is a cross-sectional view showing a configuration in which HBTs are connected in parallel to one another according to the present invention.

FIG. 5 is a cross-sectional view showing another configuration in which HBTs are connected in parallel to one another according to the present invention.

FIG. 6A is a plan view of a collector top hetero bipolar transistor of the present invention.

FIG. 6B is a cross-sectional view of the collector top hetero bipolar transistor of the present invention.

FIG. 6C is another cross-sectional view of the collector top hetero bipolar transistor of the present invention.

FIGS. 7A to 7H are cross-sectional views illustrating sequential process steps in a method for manufacturing a collector top hetero bipolar transistor according to the present invention.

FIG. 8A is a plan view of an emitter top hetero bipolar transistor of the present invention.

FIG. 8B is a cross-sectional view of the emitter top hetero bipolar transistor of the present invention.

FIG. 8C is another cross-sectional view of the emitter top hetero bipolar transistor of the present invention.

FIG. 9A is a plan view of a collector top hetero bipolar transistor of the present invention.

FIG. 9B is a cross-sectional view of the collector top hetero bipolar transistor of the present invention.

FIG. 9C is another cross-sectional view of the collector top hetero bipolar transistor of the present invention.

FIG. 10 is a layout diagram showing a two-stage power amplifier of the present invention as viewed from its rear surface.

FIG. 11 shows an equivalent circuit of the two-stage power amplifier.

FIG. 12 is a cross-sectional view schematically showing an exemplary arrangement of transistors and capacitance elements in the circuit shown in FIG. 11.

FIG. 13 is a plan view of a power amplifier module of the present invention.

FIG. 14A is a plan view of a high electron mobility transistor of the present invention.

FIG. 14B is a cross-sectional view of the high electron mobility transistor of the present invention.

FIGS. 15A to 15E are cross-sectional views illustrating sequential process steps in a method for manufacturing a high electron mobility transistor according to the present invention.

FIG. 16 is a plan view of a portion of a conventional power amplifier MMIC.

### DETAILED DESCRIPTION OF THE PREFERRED EMBODIMENTS

Prior to detailed description of preferred embodiments of the present invention, a simplified example of the principal embodiment of the present invention will be described to facilitate the understanding of the present invention.

As described above, the principal embodiment of the present invention is configured such that: the capacitance element for each internal semiconductor device is formed right under one terminal of the semiconductor device; and one of the two electrodes of the capacitance element is connected to the terminal on its underside.

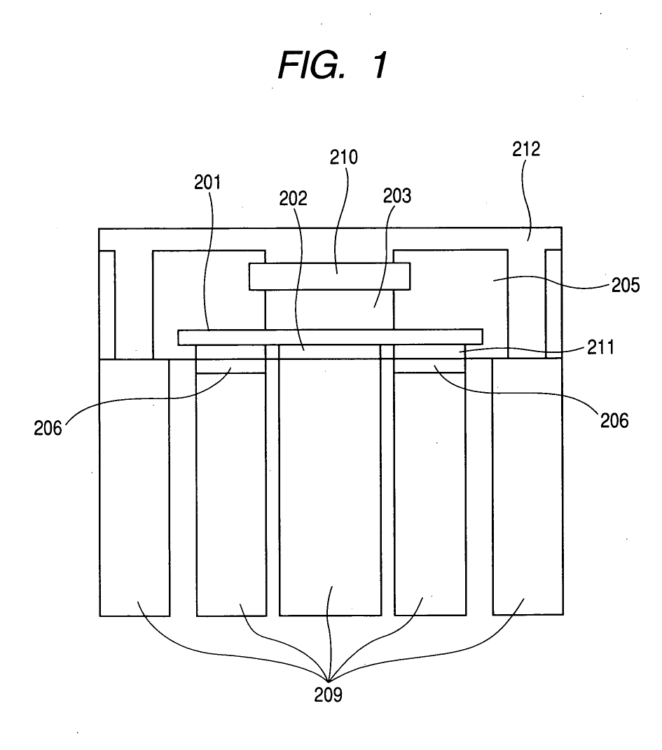

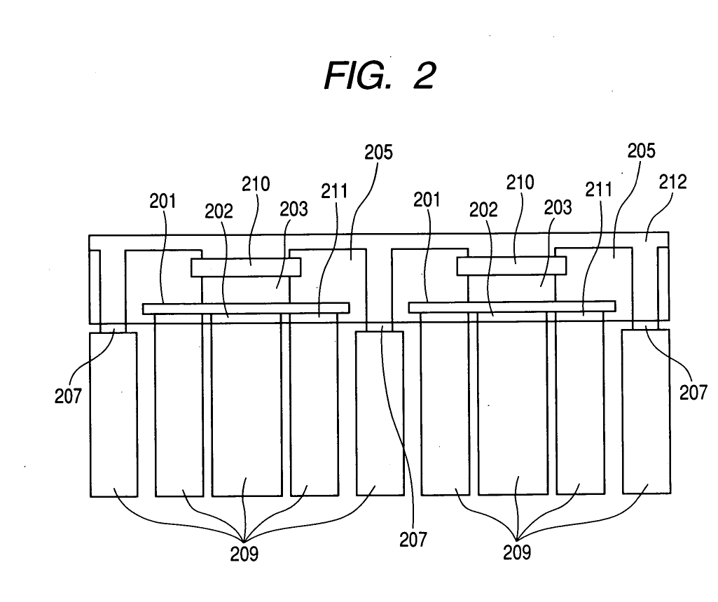

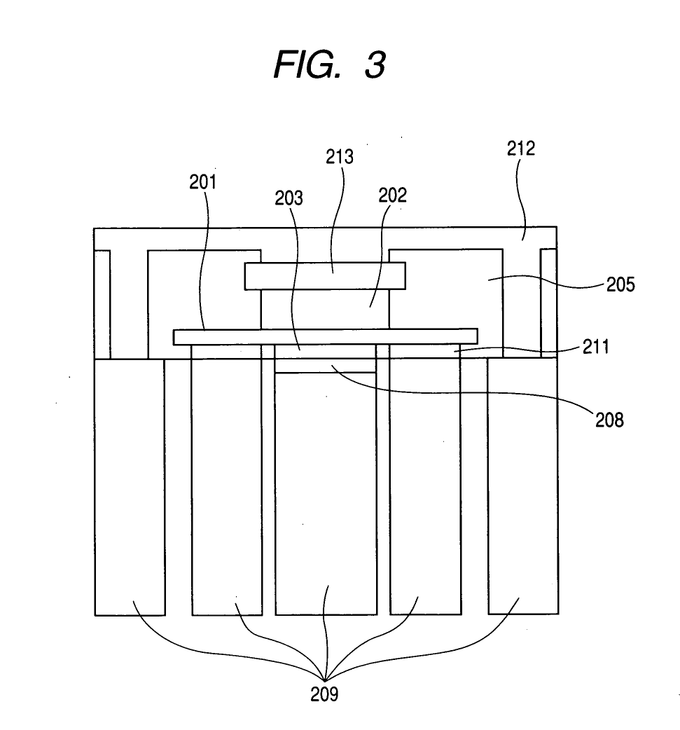

FIGS. 1 to 3 schematically show exemplary arrangements of capacitance elements for bipolar transistors. However, the present invention is not limited to these particular arrangements. A different arrangement or a combination of these exemplary arrangements may be employed depending on the design of the device. FIG. 1 shows an exemplary configuration of a collector top HBT in which the capacitance element is provided right under the base layer. As shown in the figure, an emitter 202, a base 201, and a collector 203 are laminated to one another in that order. Reference numeral 210 denotes a collector electrode; 205, an insulating layer; 211, a base electrode layer; and 212, a collector wiring conductor layer. In this HBT, a dielectric layer 206 (for the capacitance element) is disposed on the substrate side of the base electrode layer 211. The dielectric layer 206 is sandwiched between the base electrode layer 211 and bump conductors 209, forming a capacitance. FIG. 2 shows an exemplary configuration in which a plurality of collector top HBTs are connected in parallel to one another. In this configuration, the collector layer wire is disposed between the HBTs connected in parallel, and a capacitance element is disposed right under the collector wire. In this figure, components common to FIG. 1 are designated by the same reference numerals. In this example, a dielectric layer 207 (for the capacitance element) is disposed on the substrate side of the collector wiring conductor layer 212. The dielectric layer 207 is sandwiched between the collector wiring conductor layer 212 and bump conductors 209, forming a capacitance. FIG. 3 shows an exemplary configuration of an emitter top HBT in which the capacitance element is provided right under the collector layer. In this figure, components common to FIG. 1 are designated by the same reference numerals. It should be noted that reference numeral 213 denotes an emitter electrode. In this example, a dielectric layer 208 (for the capacitance element) is disposed on the substrate side of the collector layer 203. The dielectric layer 208 is sandwiched between the collector layer 203 and a bump conductor 209, forming a capacitance. It should be noted that generally a conductor layer for the capacitance element is provided on the collector layer 203 side of the dielectric layer 208, and the collector layer 203 is formed on this conductor layer. However, this conductor layer has been omitted from FIG. 3.

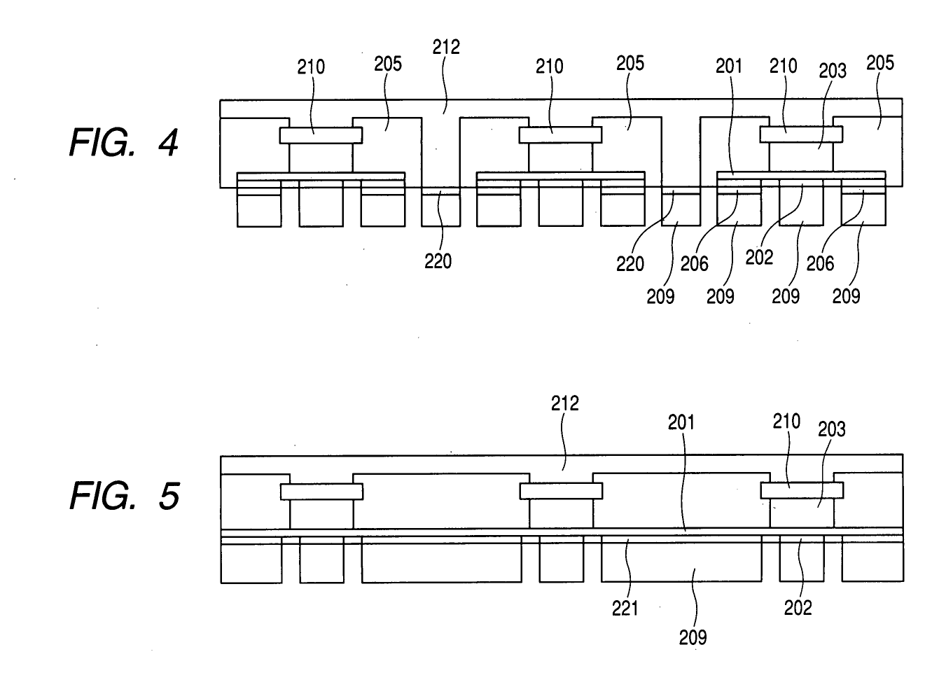

FIGS. 4 and 5 are cross-sectional views schematically showing examples in which a plurality of transistors as described above are arranged in parallel. Specifically, each example includes three HBTs connected in parallel. It should be noted that in these figures, components common to FIGS. 1 to 3 are designated by the same reference numerals. In the example shown in FIG. 4, some capacitance elements are connected to the conductor layers connected to the collector layers, and others are connected to the undersides of the base layers. Specifically, a dielectric layer 206 and a conductive layer (or bump) 209 are disposed under the base 201 of each HBT, and a dielectric layer 220 and a conductor layer (or bump) 209 are disposed under each substrate side end of the wiring conductor layer 212 covering each collector electrode 210. In the example shown in FIG. 5, on the other hand, the three HBTs share the common base layer 201, and each capacitance element is connected to the underside of this base layer 201. It should be noted that the present invention is not limited to the examples described above, but covers various arrangements included within the spirit and scope thereof.

### First Embodiment

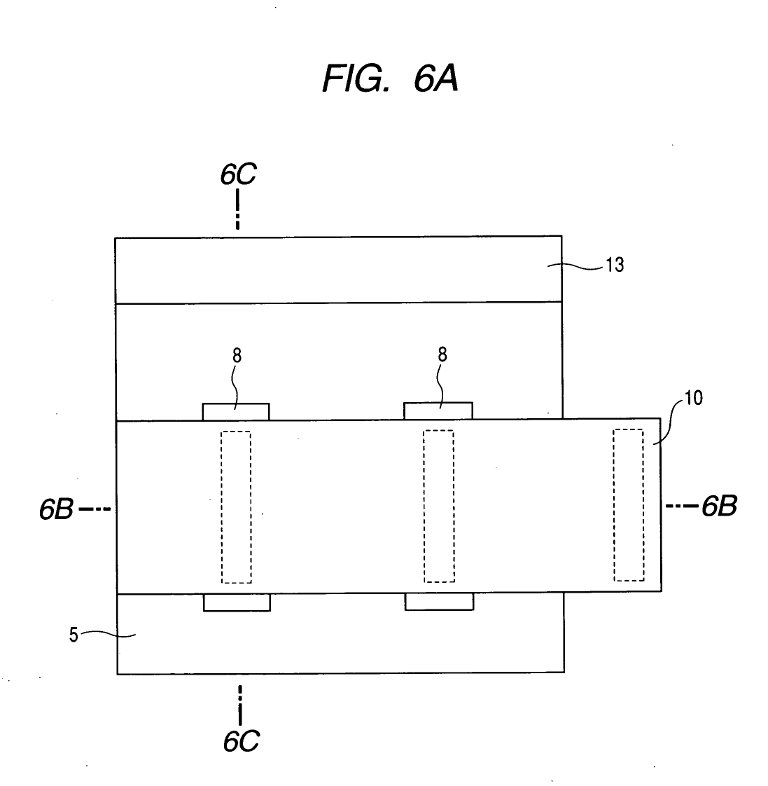

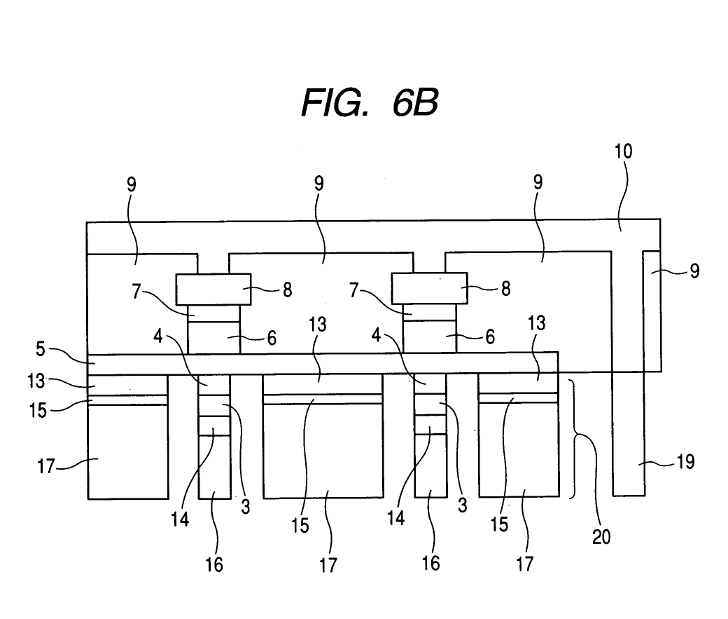

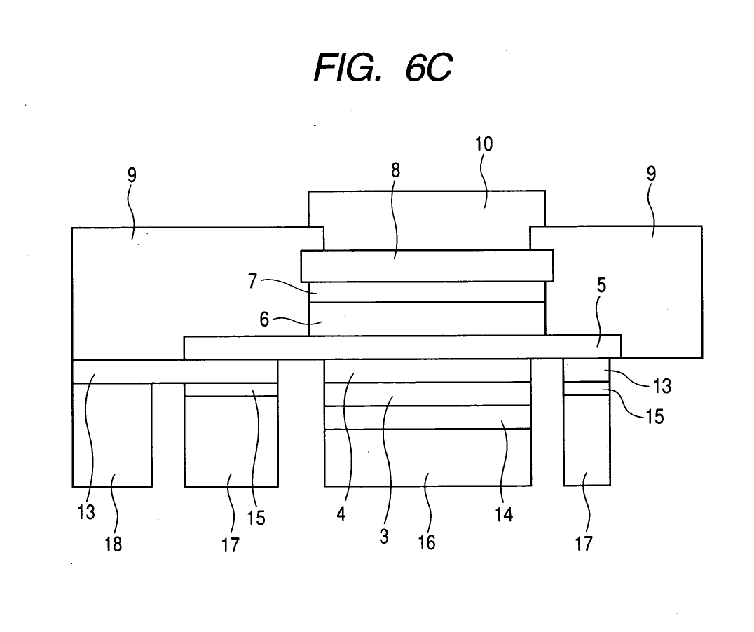

FIG. 6 (including FIGS. 6A to 6C) is a diagram showing the structure of a collector top hetero bipolar transistor (C-top HBT) within an MMIC according to the present invention. FIG. 6A is a layout diagram of the surface of the structure; FIG. 6B is a cross-sectional view of the structure taken along line 6B-6B of FIG. 6A; and FIG. 6C is a cross-sectional view of the structure taken along line 6C-6C of FIG. 6A. As shown in FIGS. 6A, 6B, and 6C, the device portion includes an n-GaAs sub-emitter layer 3, an n-InGaP emitter layer 4, a p-GaAs base layer 5, an n-GaAs collector layer 6, and an n-GaAs collector capping layer 7 formed from bottom to top in that order. WSi collector electrodes 8 are formed on the n-GaAs collector capping layer 7. The WSi collector electrodes 8 are connected to the module substrate through an Au wire 10 formed on the WSi collector electrodes 8 and through collector bumps 19. Emitter electrodes 14 and emitter bumps 16 (for module mounting) are formed right under the n-GaAs sub-emitter layer 3. On the other hand, base electrodes 13, dielectric films 15, and base bumps 17 (for module mounting) are formed right under the p-GaAs base layer 5. Each dielectric film 15 is sandwiched between a respective base electrode 13 and a respective base bump 17 (both made of metal), forming an MIM capacitance element 20. A region for DC signal input is formed for the base electrodes 13 at the same time as the region for high-frequency signal input. The DC signal is input to the base electrodes 13 through a base bump 18, not through a capacitance element.

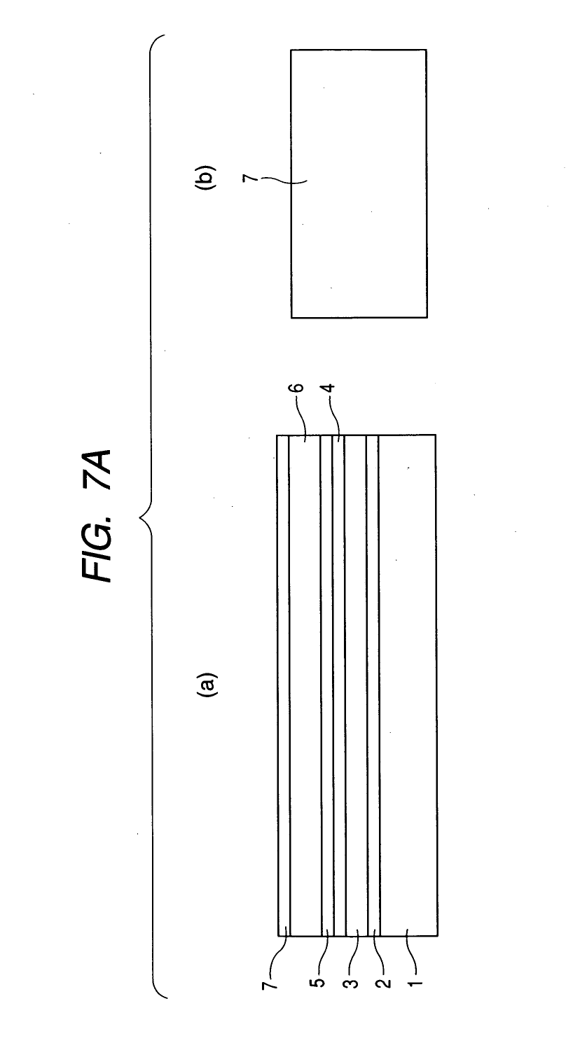

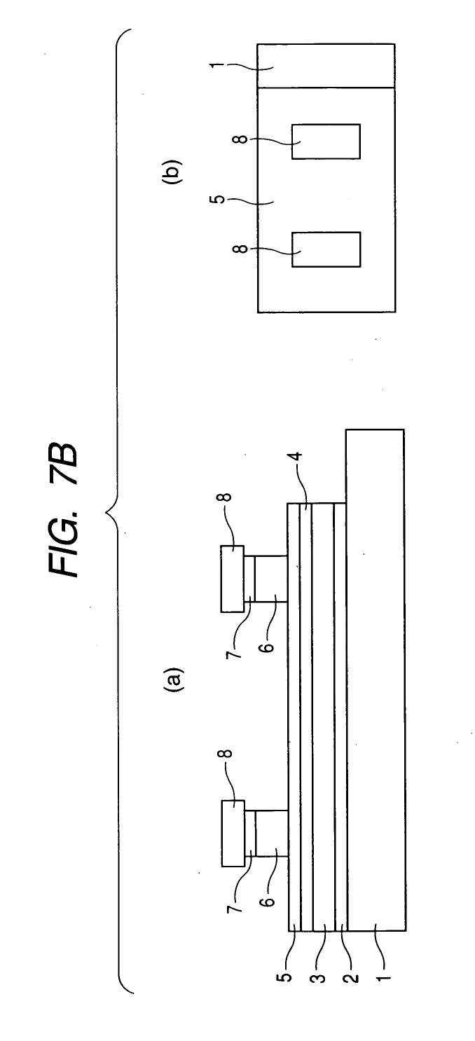

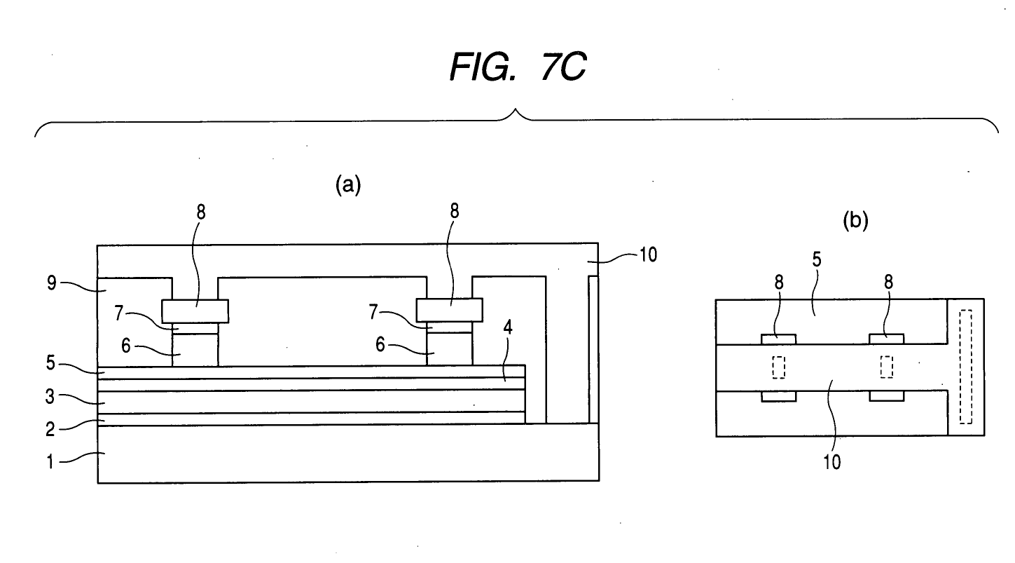

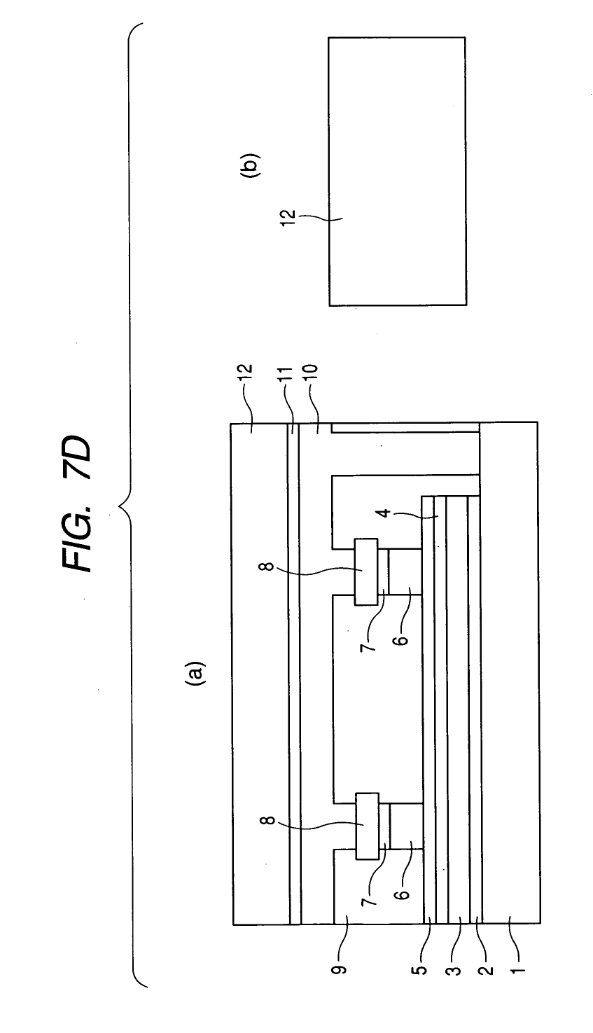

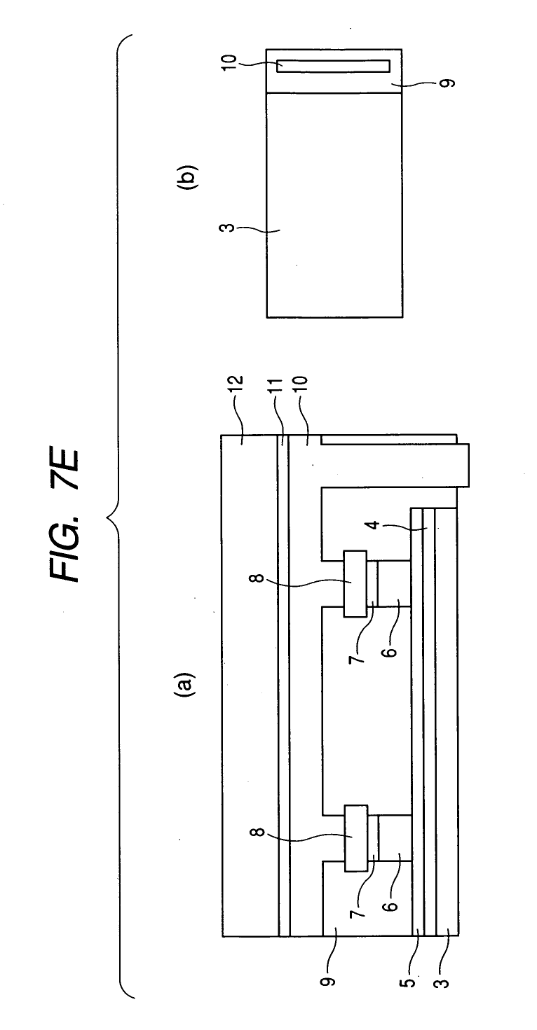

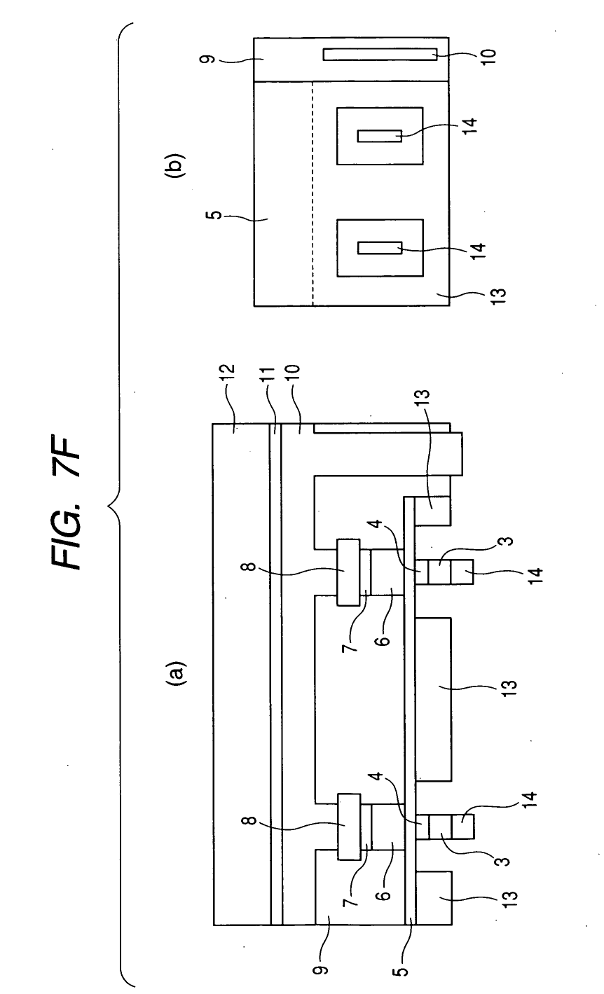

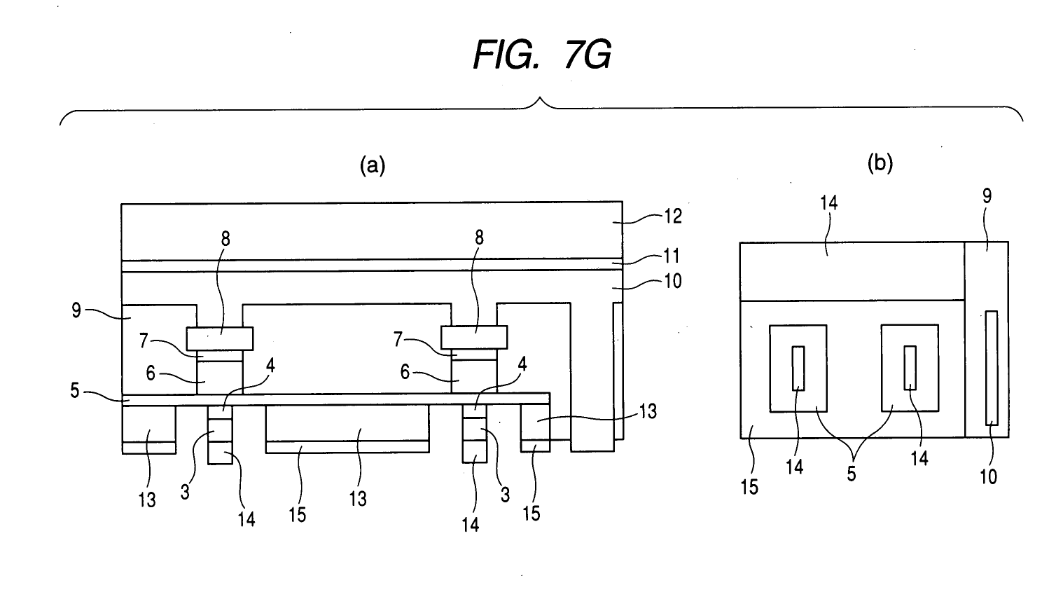

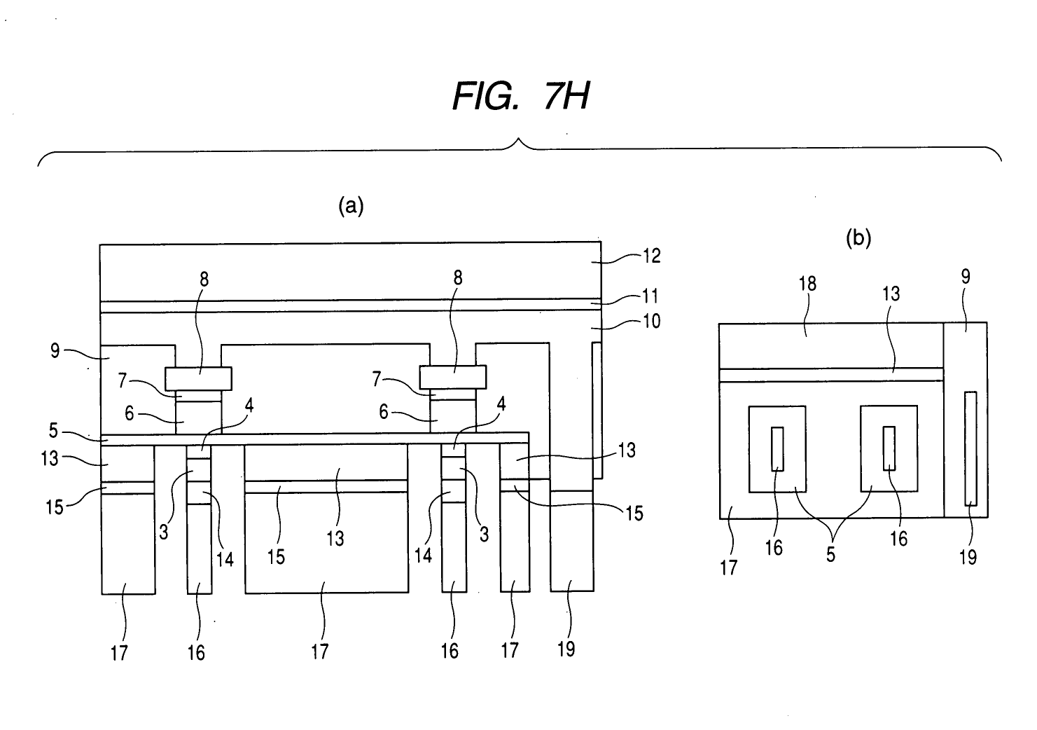

There will be now described a method for manufacturing the collector top hetero bipolar transistor with reference to the process flow diagram shown in FIGS. 7A to 7H. In each figure, left illustration (a) shows a cross-sectional structure, while right illustration (b) shows a surface structure. Specifically, FIGS. 7A to 7D each show a cross-sectional view and a plan view as viewed from the top surface, while FIGS. 7E to 7H each show a cross-sectional view and a plan view as viewed from the back surface.

First of all, over a GaAs substrate 1 are formed a 200 nm n-InGaP etching stopper layer 2 (Si-doped: 3.0×10¹⁸ cm⁻³), a 1000 nm n-GaAs sub-emitter layer 3 (Si-doped: 5.0×10¹⁸ cm⁻³), a 100 nm n-InGaP emitter layer 4 (Si-doped: 3.0×10¹⁷ cm⁻³), a 30 nm p-GaAs base layer 5 (C-doped: 3.0×10¹⁷ cm⁻³), an 800 nm n-GaAs collector layer 6 (Si-doped: 1.0×10¹⁶ cm⁻³), and a 50 nm n-GaAs collector capping layer 7 (Si-doped: 5.0×10¹⁸ cm⁻³) in that order, as shown in FIG. 7A.

Then, WSi is formed on the entire wafer surface to a thickness of 400 nm as a material for collector electrodes. After that, a photoresist is formed to have a collector electrode pattern. Then, the WSi layer is processed using the photoresist as a mask to form WSi collector electrodes 8. After this step, the photoresist is removed. Then, the n-GaAs collector capping layer 7 and the n-GaAs collector layer 6 are etched using the WSi collector electrodes 8 as masks. After that, a photoresist pattern for isolation is formed on the HBT region, and then the p-GaAs base layer 5, the n-InGaP emitter layer 4, the n-GaAs sub-emitter layer 3, and the n-InGaP etching stopper layer 2 are etched using the photoresist pattern as a mask to partially remove these layers. After this step, the photoresist is removed (see FIG. 7B).

Then, an SiO₂ film 9 is formed on the entire wafer surface as an interlayer insulating film. After that, contact holes are formed on the WSi collector electrodes 8 and in the regions surrounding the HBT region, and an Au wire 10 is formed, as shown in FIG. 7C. At that time, if the diameter of each contact hole is approximately equal to the thickness of the SiO₂ film 9 (that is, 1 μm-2 μm or more), then no problem arises in the process.

Then, the wafer surface is bonded to a bonding substrate 12 by an adhesive 11 after the formation of a protective layer, etc. (not shown) on the surface as necessary, completing the surface process, as shown in FIG. 7D.

Then, the thickness of the GaAs substrate 1 is reduced to 10 μm or less by removing material from its back surface through polishing, etc. After that, the remaining GaAs substrate 1 is selectively wet etched until the n-InGaP etching stopper layer 2 is reached, using an etchant produced as a result of adding 20 mg of citric acid and 35 ml of 50% hydrogen peroxide solution to purified water (hereinafter referred to as “citric acid-based etchant”). Then, the n-InGaP etching stopper layer 2 is etched off by hydrochloric acid (see FIG. 7E).

The etching rate of GaAs in the citric acid-based etchant is 150 nm/min when the temperature of the solution is 3° C. The etching selectivity ratio of GaAs to InGaP is 1000:1 (or a higher ratio) at this rate. This means that highly selective etching can be achieved by etching the substrate in the above etchant for 90 minutes. That is, the GaAs substrate 1 can be completely removed without penetration of the n-InGaP etching stopper layer 2.

Then, a photoresist pattern is formed on portions of the wafer other than the base electrode formation region, and the n-GaAs sub-emitter layer 3 and the n-InGaP emitter layer 4 are etched using the photoresist pattern as a mask. After that, a base electrode metal made of Au/Pt/Ti/Pt is formed on the entire surface, and the base electrodes 13 are formed by a lift-off technique using the n-GaAs sub-emitter layer 3 as a lift-off spacer. At that time, an additional base electrode region is formed outside the region in which capacitance elements are formed (see FIG. 7F (b)). (This region is used as a wiring formation region for DC signal input.) Then, an SiO₂ film (not shown) is formed on the entire surface, and a photoresist is formed on regions other than the n-GaAs sub-emitter layer 3. Then, after the SiO₂ film has been processed using the photoresist as a mask, an emitter electrode metal made of Au/Ni/AuGe is formed on the entire surface. Then, the emitter electrodes 14 are formed by a lift-off technique using the SiO₂ film as a lift-off spacer (see FIG. 7F)

Then, a photoresist pattern is formed on portions other than the base electrodes 13, and then the SiO₂ film is processed using the photoresist pattern as a mask. After this step, the photoresist is removed. Then, a dielectric film 15 having a three-layer structure made up of SiO₂/SiN/SiO₂ is formed on the entire surface. After that, a photoresist pattern is formed only on the capacitance element formation portions, and the dielectric film 15 is processed using the photoresist as a mask. After this step, the photoresist is removed (see FIG. 7G).

Then, after the formation of a plating seed electrode on the entire surface, a photoresist pattern is formed which has openings exposing the emitter bump formation regions, the base bump formation regions (for both high-frequency and DC signals), and the collector bump formation region. After that, Au plating is applied to these exposed regions. Then, unwanted portions of the seed electrode are removed after removal of the photoresist, thereby forming the emitter bumps 16, the high-frequency signal base bump 17, the DC signal base bump 18, and the collector bump 19. As a result, the capacitance element 20 made up of the base electrodes 13, the dielectric film 15, and the high-frequency signal base bump 17 is formed right under the base layer.

The above process completes formation of the MMIC (i.e., the HBT and capacitance element portions).

This structure allows one to form under the HBT all the regions for accommodating the capacitance element itself and the wire connecting between one end of the capacitance element and the HBT, resulting in a great reduction in the required chip area.

Further, conventionally, the through-holes (via holes, etc.) for connecting the top and back surfaces must have a diameter at least approximately equal to the thickness of the substrate in order to ensure sufficient process performance. However, since the present invention removes the GaAs substrate 1 entirely or at least the portions of the GaAs substrate 1 in the regions in which the HBT and the capacitance element are formed, the through-holes for connecting the top and back surfaces may be formed to a diameter approximately equal to the thickness of the SiO₂ film 9 (i.e., 1 μm-2 μm), also resulting in a great reduction in the required chip area.

Further, since the GaAs substrate 1 is processed using citric acid etchant, the HBT suffers no damage during the etching process, thus achieving high-accuracy, high-selectivity, yet low-cost etching.

### Second Embodiment

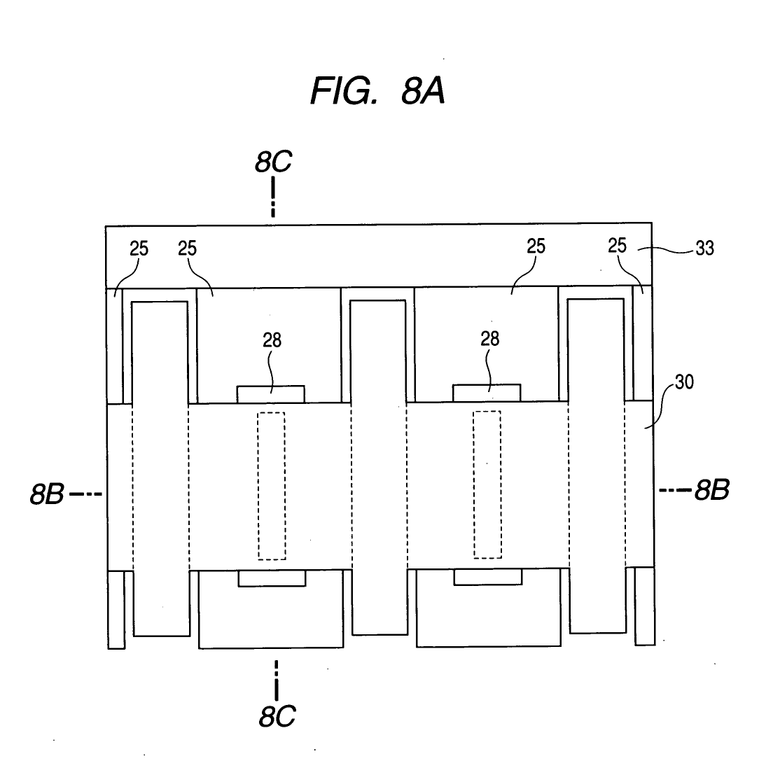

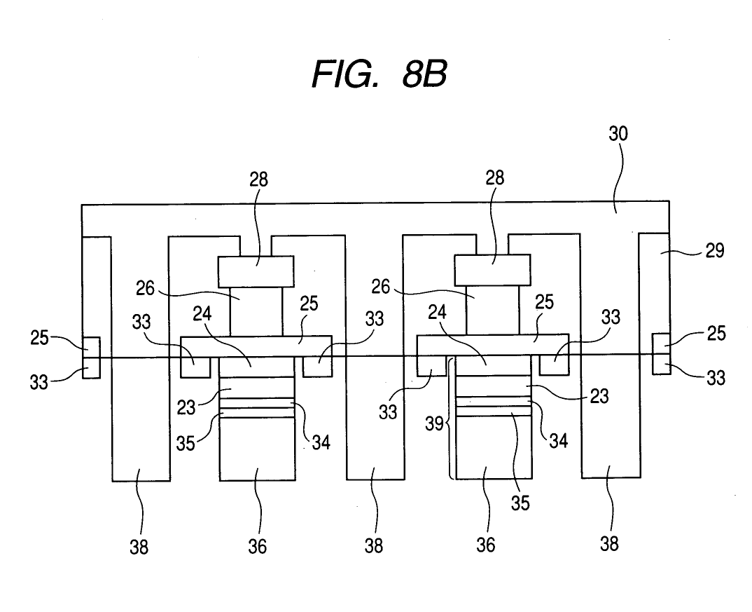

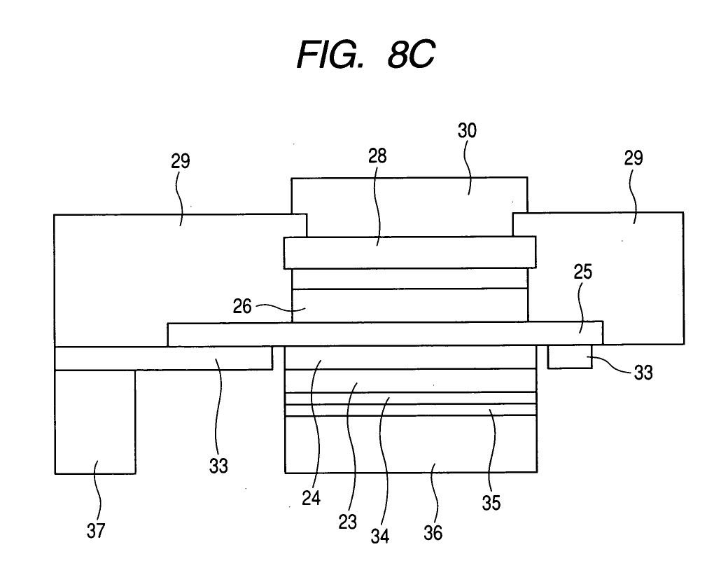

FIGS. 8A to 8C are diagrams showing the structure of an emitter top HBT (E-top HBT) within an MMIC according to the present invention. Specifically, FIG. 8A is a layout diagram of the surface of the structure; FIG. 8B is a cross-sectional view of the structure taken along line 8B-8B of FIG. 8A; and FIG. 8C is a cross-sectional view of the structure taken along line 8C-8C of FIG. 8A. As shown in FIGS. 8B and 8C, the device portion includes an n-GaAs sub-collector layer 23, an n-InGaP collector layer 24, a p-GaAs base layer 25, and an n-GaAs emitter layer 26 formed from bottom to top in that order. WSi emitter electrodes 28 are formed on the n-GaAs emitter layer 26. The WSi emitter electrodes 28 are connected to the module substrate through an Au wire 30 formed on the WSi emitter electrodes 28 and through emitter bumps 38. Collector electrodes 34, dielectric films 35, and collector bumps 36 (for module mounting) are formed right under the n-GaAs sub-collector layer 23. Each dielectric film 35 is sandwiched between a respective collector electrode 34 and a respective collector bump 36 (both made of metal), forming an MIM capacitance element 39. On the other hand, base electrodes 33 and a base bump 37 are formed right under the p-GaAs base layer 25.

This structure allows one to form under the HBT all the regions for accommodating the capacitance element itself and the wire connecting between one end of the capacitance element and the HBT, resulting in a great reduction in the required chip area.

### Third Embodiment

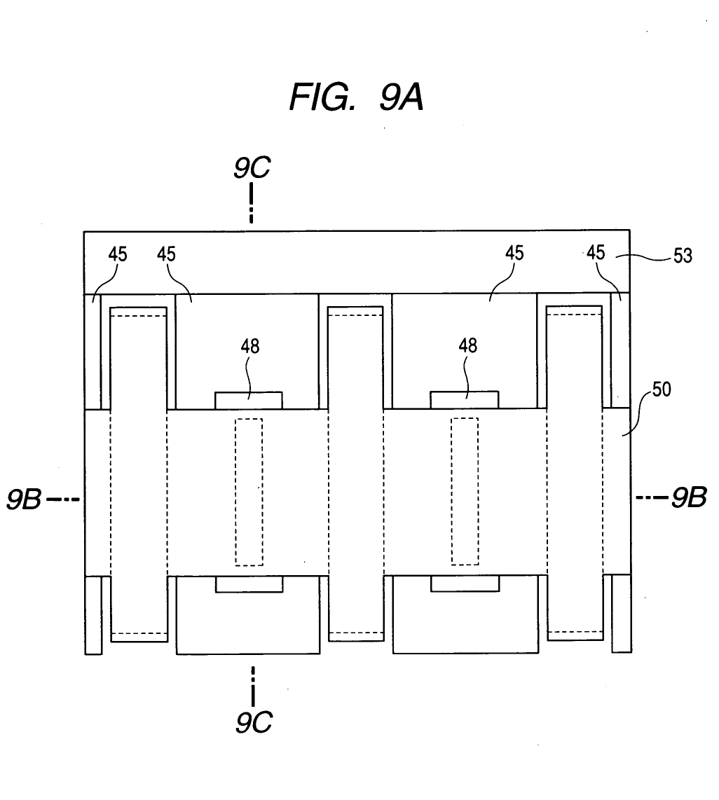

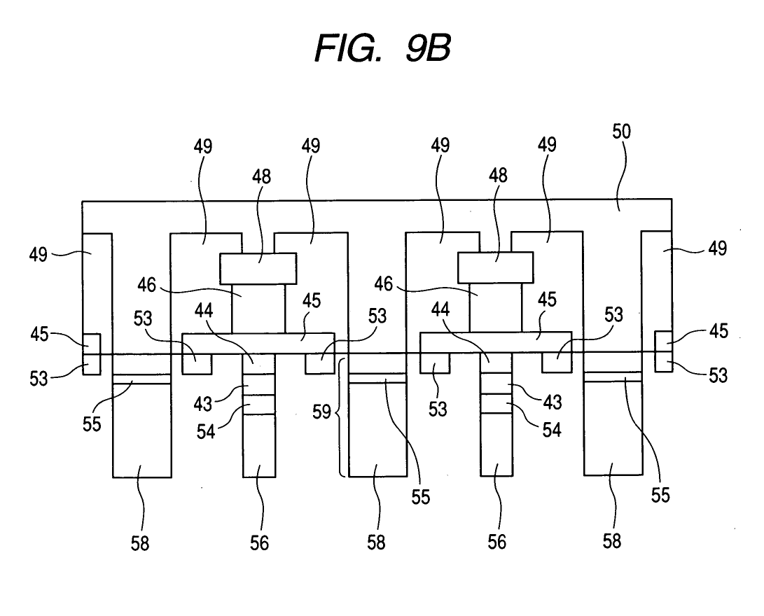

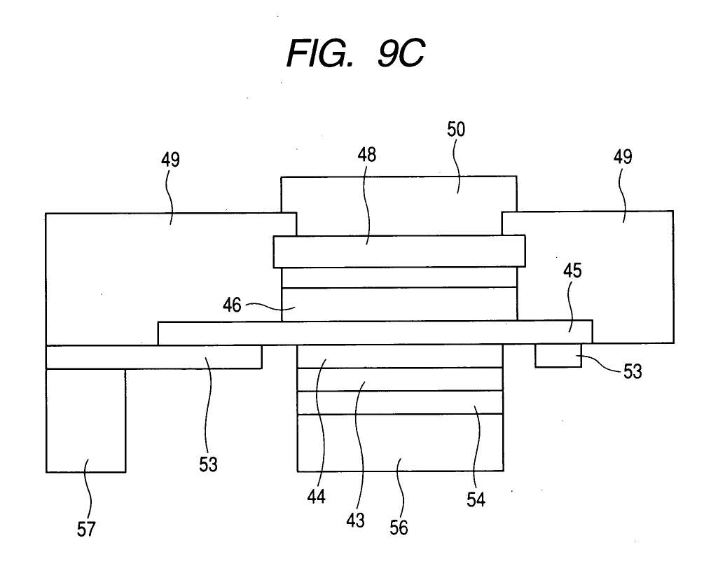

FIGS. 9A to 9C are diagrams showing the structure of another C-top HBT within an MMIC according to the present invention. Specifically, FIG. 9A is a layout diagram of the surface of the structure; FIG. 9B is a cross-sectional view of the structure taken along line 9B-9B of FIG. 9A; and FIG. 9C is a cross-sectional view of the structure taken along line 9C-9C of FIG. 9A.

As shown in FIGS. 9B and 9C, the device portion includes an n-GaAs sub-emitter layer 43, an n-InGaP emitter layer 44, a p-GaAs base layer 45, and an n-GaAs collector layer 46 formed from bottom to top in that order. WSi collector electrodes 48 are formed on the n-GaAs collector layer 46. The WSi collector electrodes 48 are connected to the module substrate through an Au wire 50 formed on the WSi collector electrodes 48 and through collector bumps 49. Dielectric films 55 and collector bumps 58 are formed such that each dielectric film 55 is sandwiched between a respective collector bump 58 and the Au wire 50, forming an MIM capacitance element 59. Further, emitter electrodes 54 and emitter bumps 56 (for module mounting) are formed right under the n-GaAs sub-emitter layer 43, while base electrodes 53 and a base bump 57 are formed right under the p-GaAs base layer 45.

In the above configuration, all capacitance elements are disposed in redundant regions between fingers of the multi-finger HBT, thereby minimizing the chip area for these capacitance elements. Furthermore, this structure allows one to form under the HBT all the regions for accommodating the wires connecting one end of each capacitance element to the HBT, resulting in a great reduction in the required chip area.

### Fourth Embodiment

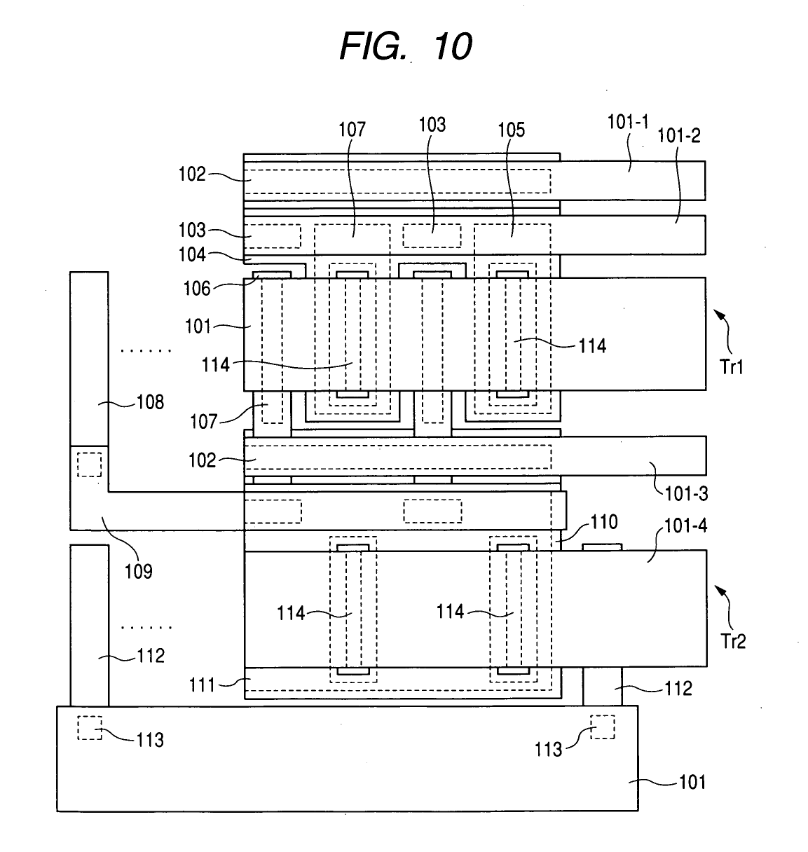

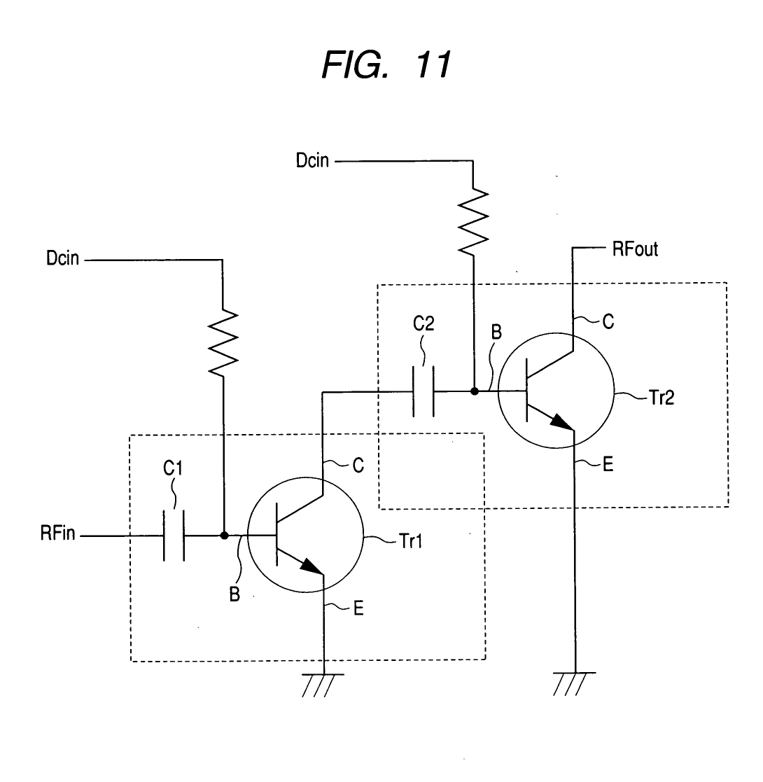

FIG. 10 is a layout diagram showing a two-stage power amplifier of the present invention as viewed from its rear surface. Both the first- and second-stage HBTs are multi-finger HBTs with capacitance elements according to the present invention. They are connected to each other by module wire 101, etc. FIG. 11 shows an equivalent circuit of this amplifier. The transistors Tr1 and Tr2 in the equivalent circuit of FIG. 11 correspond to the components (or transistors) Tr1 and Tr2, respectively, in FIG. 10. The input terminals DCin and RFin of the transistor Tr1 shown in FIG. 11 correspond to the portions 101-1 and 101-2, respectively, in FIG. 10. The input terminal DCin of the transistor Tr2 shown in FIG. 11 corresponds to the portion 101-3 in FIG. 10. Further, the output RFout of the transistor Tr2 shown in FIG. 11 is made up of the portions 101 and 113 in FIG. 10. In FIG. 11, symbols B, E, and C denote a base, an emitter, and a collector, respectively. It should be noted that in FIG. 10, reference numeral 114 denotes an emitter bump. The operation of the two-stage power amplifier is well known in the art and therefore will not be described.

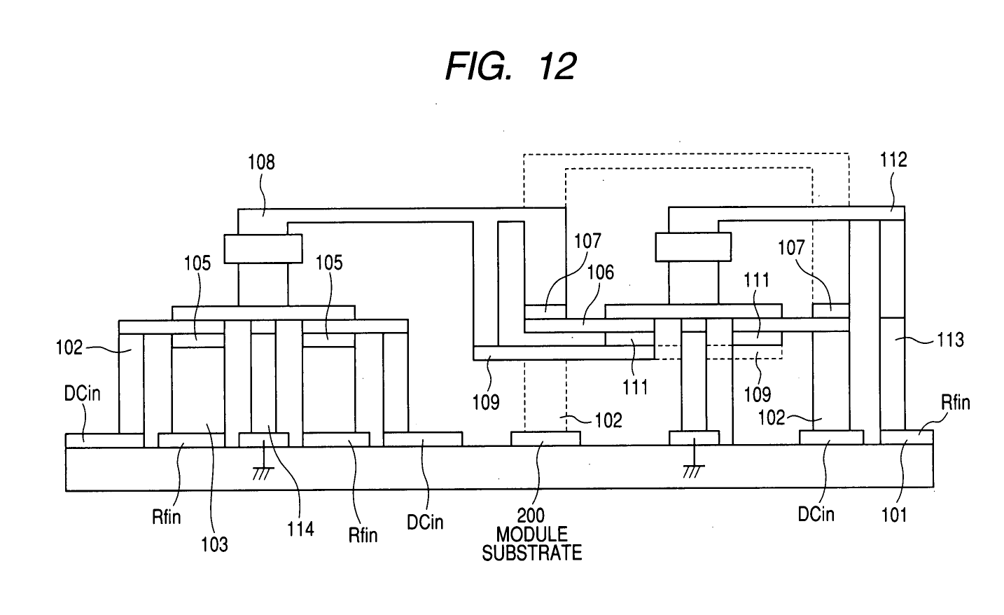

FIG. 12 shows an exemplary arrangement of capacitance elements C1 and C2 connected to the transistors Tr1 and Tr2, respectively. These transistors are configured as described above. It should be noted that FIG. 12 is a schematic diagram illustrating interconnections between the circuit components. Specifically, the transistor Tr1 is actually made up of a plurality of semiconductor active devices connected in parallel to one another, and the figure shows only two of them. The portions (or capacitance elements) denoted by reference numerals 105 and 107 in the figure constitute the capacitance (element) C1 connected to the transistor Tr1. As for the capacitance C2 connected to the transistor Tr2, it is made up of two types of capacitance elements: a first capacitance element C2-1 formed under the base layer; and a second capacitance element C2-2 inserted into the wiring conductor connecting between the base layer of the transistor Tr2 and the collector of the transistor Tr1. Thus, a desired capacitance may be achieved by using capacitance elements formed at different places.

The structure of the two-stage power amplifier will now be described in detail. The DC and high-frequency signals are input to the amplifier through the input terminals DCin and Rfin, respectively, on the wire 101 formed on the module substrate. The DC signal is directly input to the base electrode of the first-stage HBT through a DC signal base bump 102. The high-frequency signal, on the other hand, is input to the base electrode of the first-stage HBT through a high-frequency signal base bump 103 and the capacitance element 105 (which is made up of a dielectric film sandwiched between the base electrode and a rear wire 104). The output signal from the first-stage HBT is input to the base electrode of the second-stage HBT through the capacitance element 107 (which is made up of a dielectric film sandwiched between a rear wire 106 and the collector wire extending from the collector layer of the first-stage HBT to each finger). The output signal from the first-stage HBT is also input to the base electrode of the second-stage HBT through the collector wire extending from the collector layer of the first-stage HBT to each finger, and through a collector wire 108 extending from the collector layer to a region surrounding the first-stage HBT, a rear wire 109, and a capacitance element 111 (which is made up of a dielectric film sandwiched between the base electrode and a rear wire 110). Thus, the capacitance element 107 formed between fingers of the first-stage HBT is connected (or disposed) in parallel to the capacitance element 111 formed right under the base electrode of the second-stage HBT, thereby utilizing redundant regions. This structure allows one to form a capacitance element having a large area between the output of the first-stage HBT and the input of the second-stage HBT. Then, the amplified signal is output to the module wire 101 through a collector wire 112 extending from the collector layer of the second-stage HBT to a region surrounding the second-stage HBT and a collector bump 113.

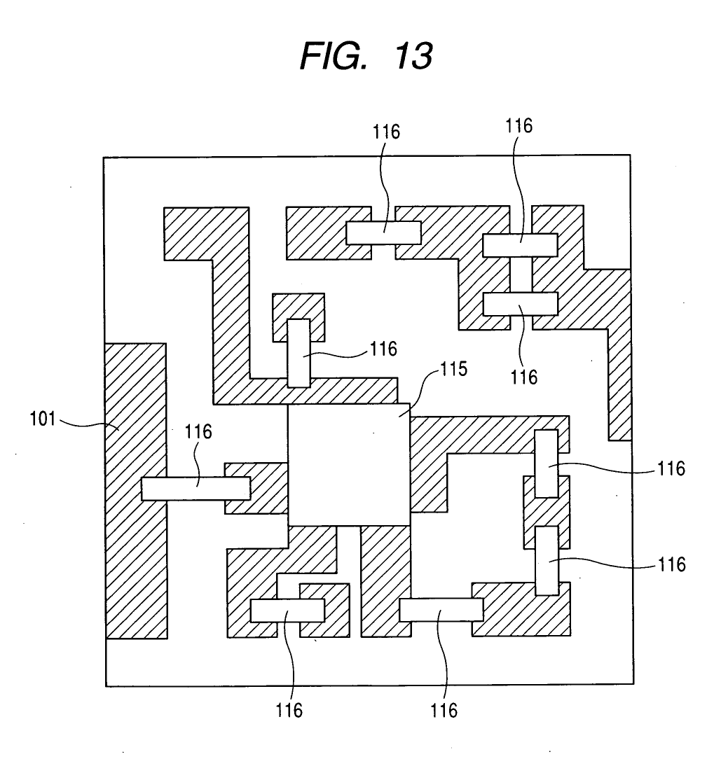

FIG. 13 is a plan view of a power amplifier module. This module is made up of an MMIC chip 115 and passive devices 116 connected to one another by module wire 101.

According to the present embodiment, capacitance elements are disposed right under the collector wire or the base electrode of an HBT. However, this arrangement is merely representative and not limiting. For example, an additional capacitance element may be provided right under the emitter electrode, depending on the circuit configuration.

### Fifth Embodiment

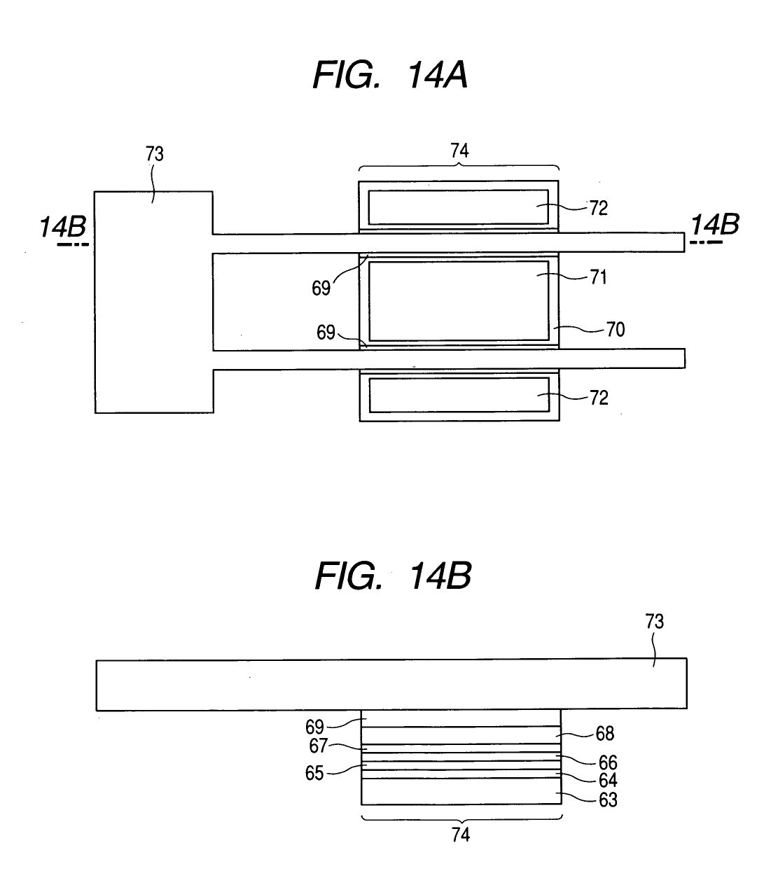

FIG. 14 (including FIGS. 14A and 14B) is a diagram showing the structure of a strained channel HEMT according to the present invention. FIG. 14A is a layout diagram of the surface of the structure; and FIG. 14B is a cross-sectional view of the structure taken along line 14B-14B of FIG. 14A.

Referring to FIGS. 14A and 14B, this strained channel HEMT is configured such that: a source electrode 71 and drain electrodes 72 are formed on an n-GaAs capping layer 70; the portions of the n-GaAs capping layer 70 between the source electrode 71 and the drain electrodes 72 are removed so as to expose an n-Al_{0.25}Ga₇₅As layer 69; a gate electrode 73 is formed on the exposed Al_{0.25}Ga_{0.75}As layer 69; semiconductor layers under the gate electrode 73 other than a transistor active region 74 are removed; and a GaAs substrate 61 and an undoped GaAs buffer layer 62 right under the transistor active region 74 are also removed.

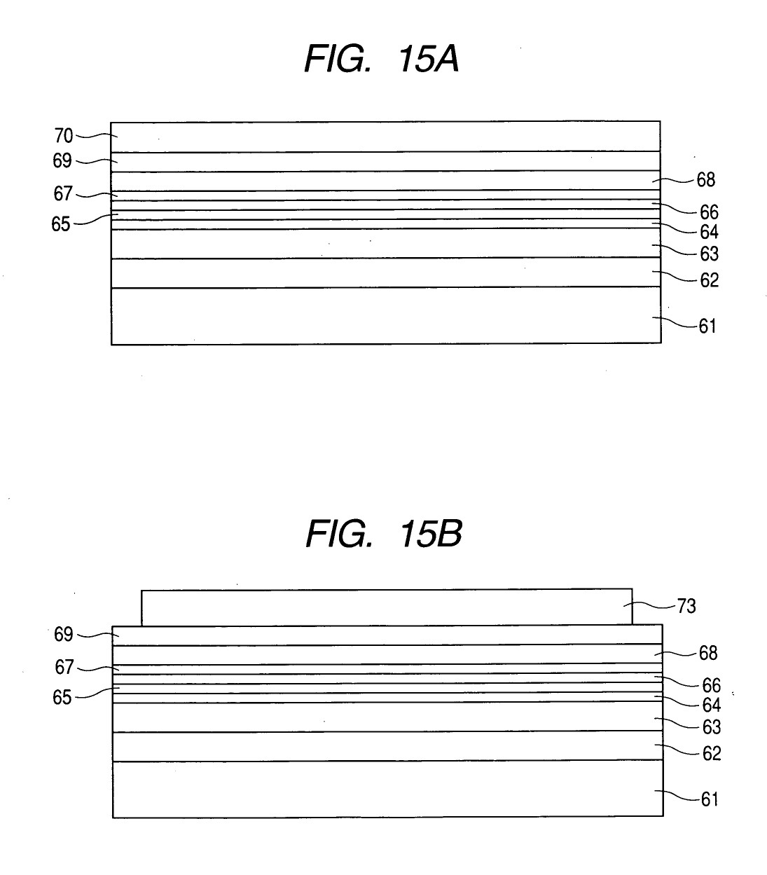

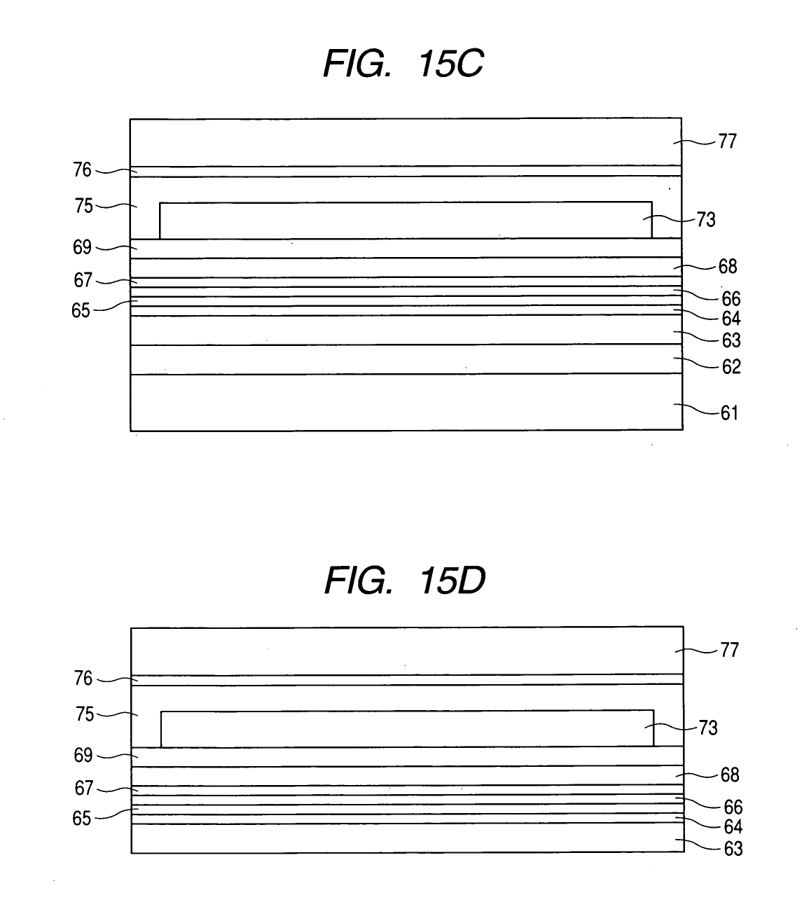

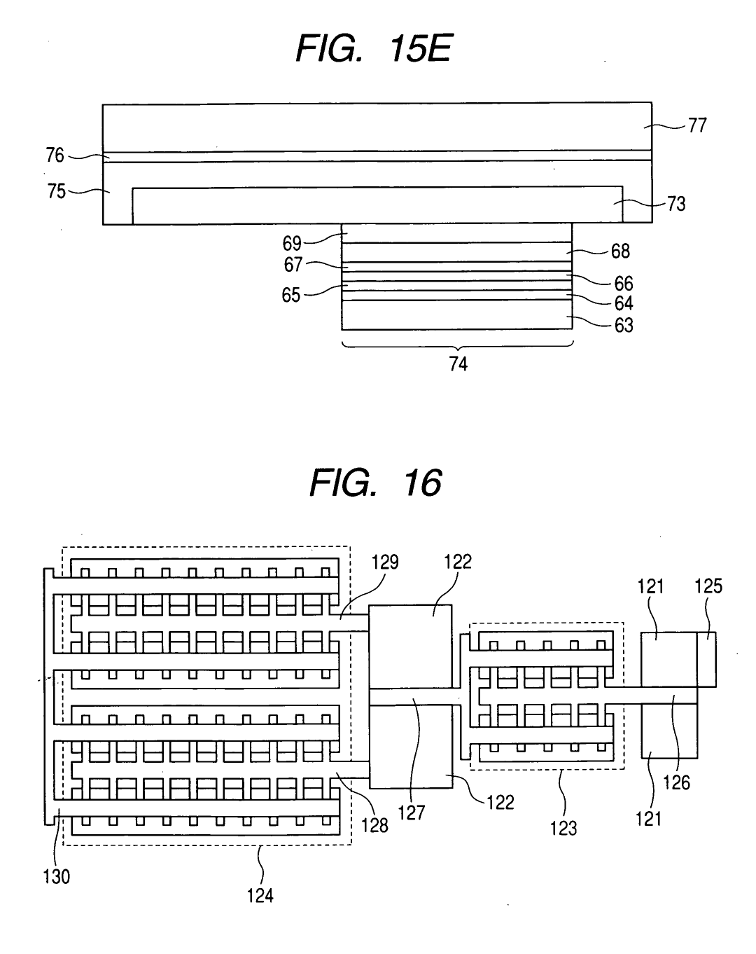

There will be now described a method for manufacturing the strained channel HEMT with reference to the process flow diagram shown in FIGS. 15A to 15E.

First of all, over a GaAs substrate 61 are epitaxially grown a 100 nm undoped GaAs buffer layer 62, a 100 nm undoped Al_{0.25}Ga_{0.75}As layer 63, a 2 nm undoped GaAs layer 64, an 8 nm undoped In_{0.25}Ga_{0.75}As active layer 65, a 2 nm undoped GaAs layer 66, a 2 nm undoped Al_{0.25}Ga_{0.75}As layer 67, a 12 nm n-Al_{0.25}Ga_{0.75}As carrier supply layer 68 (Si-doped: 4×10¹⁸ cm⁻³), a 20 nm n-Al_{0.25}Ga_{0.75}As layer 69 (Si-doped: 5×10¹⁶ cm⁻³), and a 180 nm n-GaAs capping layer 70 (Si-doped: 5×10¹⁸ cm³) in that order, as shown in FIG. 15A.

Then, the source electrode 71 and the drain electrodes 72 are formed on the n-GaAs capping layer 70 by a lift-off technique.

Then, the portions of the n-GaAs capping layer 70 between the source electrode 71 and the drain electrodes 72 are removed by wet etching so as to expose the n-Al_{0.25}Ga_{0.75}As layer 69. After that, the gate electrode 73 is formed on the n-Al_{0.25}Ga_{0.75}As layer 69 by a lift-off technique (see FIG. 15B).

Then, an SiO₂ film 75 is formed on the entire surface, and each electrode, wire, etc. (not shown) are formed. Then, the wafer surface is bonded to a bonding substrate 77 by an adhesive 76 after the formation of a protective layer, etc. (not shown) on the surface as necessary, completing the surface process, as shown in FIG. 15C.

Then, the thickness of the GaAs substrate 61 is reduced to 10 μm or less by removing material from its back surface through polishing, etc. After that, as shown in FIG. 15D, the remaining GaAs substrate 61 is selectively wet etched until the undoped Al_{0.25}Ga_{0.75}As layer 63 is reached, using an etchant produced as a result of adding 7.6 mg of citric acid and 10 ml of 50% hydrogen peroxide solution to 500 ml of purified water and then adjusting the pH of the resultant solution to 6.5 with the addition of aqueous ammonia (hereinafter referred to as “citric acid-based etchant”).

The etching rate of GaAs in the citric acid-based etchant is 50 nm/min and the etching selectivity ratio of GaAs to AlGaAs is 300:1 (or a higher ratio) when the temperature of the solution is 5° C. This means that highly selective etching can be achieved by etching the substrate in the above etchant for 200 minutes. That is, the GaAs substrate 61 can be completely removed without penetration of the undoped Al_{0.25}Ga_{0.75}As layer 63.

Then, semiconductor layers (under the gate electrode 73) other than the transistor active region 74 are removed by wet or dry etching, etc., completing production of the strained channel HEMT, as shown in FIG. 15E.

In the above structure, the gate metal is not extended to the mesa step portions. This prevents breakage of the gate metal as well as contact between the gate metal and the active layers, preventing an increase in the gate resistance and in the gate leakage current and a reduction in the gate electric strength.

Listed below are the principal aspects of the present invention. (The present invention may encompass a variety of aspects that may not be set forth below.)

(1) A first aspect of the present invention provides a microwave integrated circuit device comprising:

a semiconductor active device that includes three semiconductor layers acting as an input terminal, an output terminal, and a ground terminal, respectively, wherein at least one of the three terminals has a metal electrode formed right thereunder such that the metal electrode is in Schottky or ohmic contact with the at least one of said three terminals; and

a capacitance element that includes a first capacitance electrode, a second capacitance electrode, and a dielectric film sandwiched between the first and second capacitance electrodes, wherein the first capacitance electrode is made up of at least one of said metal electrode and a metal wire connected to the metal electrode.

(2) According to a second aspect of the present invention, the microwave integrated circuit device of the first aspect (1) is further configured such that the semiconductor active device is a bipolar transistor.

(3) According to a third aspect of the present invention, the microwave integrated circuit device of the first aspect (1) is further configured such that the capacitance element is formed right under the metal electrode or the metal wire connected to the metal electrode.

(4) According to a fourth aspect of the present invention, the microwave integrated circuit device of the first aspect (1) comprises a plurality of the semiconductor active devices connected in parallel to one another.

(5) According to a fifth aspect of the present invention, the microwave integrated circuit device of the fourth aspect (4) is further configured such that capacitance elements are formed in regions between the semiconductor active devices connected in parallel to one another.

(6) According to a sixth aspect of the present invention, the microwave integrated circuit devices of the first (1) to fifth (5) aspects are further configured such that the semiconductor substrate has been removed entirely or at least the portion of the semiconductor substrate in the region in which the semiconductor active device and/or the capacitance element is formed has been removed.

(7) A seventh aspect of the present invention provides a power amplifier comprising:

amplifier circuits connected to one another in a multistage fashion (or serially), each amplifier circuit including one or more semiconductor active devices connected in parallel to one another;

wherein each amplifier circuit may be any one of the microwave integrated circuit devices of the first (1) to sixth (6) aspects.

(8) An eighth aspect of the present invention provides a field-effect transistor comprising:

a semiconductor substrate;

a semiconductor conductive layer providing a transistor active region;

a source electrode and a drain electrode formed on the semiconductor conductive layer; and

a gate electrode formed between the source and drain electrodes and having a larger width than the transistor active region;

wherein portions of the semiconductor conductive layer and the semiconductor substrate other than those in the transistor active region have been removed, or at least the portions of the semiconductor conductive layer and the semiconductor substrate around the transistor active region have been removed; and

wherein the gate electrode formed partially on the transistor active region is located on the same plane.

(9) A ninth aspect of the present invention provides a method for manufacturing a microwave integrated circuit device, comprising the steps of:

forming a semiconductor active device that includes three semiconductor layers acting as an input terminal, an output terminal, and a ground terminal, respectively, wherein at least one of the three terminals has a metal electrode formed right thereunder such that the metal electrode is in Schottky or ohmic contact with the at least one of the three terminals; and

forming a capacitance element that includes a first capacitance electrode, a second capacitance electrode, and a dielectric film sandwiched between the first and second capacitance electrodes, wherein the first capacitance electrode is made up of at least one of the metal electrode and a metal wire connected to the metal electrode.

(10) According to a tenth aspect of the present invention, in the method of the ninth aspect (9), the semiconductor active device is a bipolar transistor, and the step of forming the semiconductor active device includes the steps of:

sequentially forming a sub-emitter layer, an emitter layer, a base layer, and a collector layer on a semiconductor substrate; and

forming an emitter electrode, a base electrode, and a collector electrode electrically connected to the emitter, base, and collector layers, respectively, wherein the emitter electrode is disposed right under the sub-emitter layer, or the base electrode is disposed right under the base layer, or both.

(11) According to an eleventh aspect of the present invention, in the method of the ninth aspect (9), the semiconductor active device is a bipolar transistor, and the step of forming the semiconductor active device includes the steps of:

sequentially forming a sub-collector layer, a collector layer, a base layer, and an emitter layer on a semiconductor substrate; and

forming a collector electrode, a base electrode, and an emitter electrode electrically connected to the collector, base, and emitter layers, respectively, wherein the collector electrode is disposed right under the sub-collector layer, or the base electrode is disposed right under the base layer, or both.

(12) According to a twelfth aspect of the present invention, in the method of the ninth aspect (9), the semiconductor active device is a field-effect transistor, and the step of forming the semiconductor active device includes the steps of:

forming an active layer on a semiconductor substrate;

forming a gate electrode above the active layer; and

forming a source electrode and a drain electrode on respective sides of the gate electrode, wherein the source and drain electrodes are electrically connected to the active layer and wherein at least one of the source and drain electrodes is disposed right under the active layer.

(13) According to a thirteenth aspect of the present invention, the method of the ninth aspect (9) further comprises the step of:

forming the capacitance element right under the metal electrode or the metal wire connected to the metal electrode.

(14) According to a fourteenth aspect of the present invention, the methods of the ninth (9) to thirteenth (13) aspects further comprise the step of:

removing the semiconductor substrate entirely or at least the portions of the semiconductor substrate in the regions in which the semiconductor active device and the capacitance element are formed.

(15) According to a fifteenth aspect of the present invention, in the method of the fourteenth aspect (14), the semiconductor substrate removing step removes the semiconductor substrate by use of a wet etching technique.

(16) A sixteenth aspect of the present invention provides a method for manufacturing a field-effect transistor comprising the steps of:

forming an active layer on a semiconductor substrate;

forming a source electrode, a drain electrode, and a gate electrode on the active layer, the source and drain electrodes being electrically connected to the active layer, the gate electrode being sandwiched between the source and drain electrodes;

removing the semiconductor substrate entirely or at least the portion of the semiconductor substrate around the region in which the source and drain electrodes and a portion of the gate electrode are formed; and

removing portions of the active layer other than those in the region in which the source and drain electrodes and the above portion of the gate electrode are formed, or removing at least the portion of the active layer around the region in which the source and drain electrodes and the above portion of the gate electrode are formed.

To facilitate the understanding of the features of the present invention, the technique of the present invention will be compared to a prior art technique. In a power amplifier MMIC, a capacitance element is connected to the input side of each internal semiconductor device to remove low frequency noise and stabilize the operation of the device. FIG. 16 is a plan view of a portion of a conventional power amplifier MMIC. A first-stage semiconductor device 123 and a second-stage semiconductor device 124 shown in FIG. 16 are connected to each other as shown in FIG. 11, for example. In FIG. 16, reference numeral 125 denotes the input terminal for high-frequency signal input, and 130 denotes the output terminal of the second-stage semiconductor device 124. The high-frequency input signal is input to the input side of the first-stage semiconductor device 123 through the wire 125, a capacitance element 121, and a wire 126, and then output from the output side of the first-stage semiconductor device 123. The signal output from the first-stage semiconductor device 123 is input to the second-stage semiconductor device 124 through a wire 127, a capacitance element 122, and wires 128 and 129. Then, the signal is amplified and output through a wire 130.

Conventionally, the above capacitance elements 121 and 122 (capacitances required for the devices) are arranged horizontally on planar regions around the semiconductor devices. That is, the conventional technique requires one to reserve regions for these capacitance elements on the semiconductor chip. The present invention eliminates this requirement.

As described above in detail, the present invention allows one to reduce the area for the wires connecting between the top and back surfaces, as well as the area for the capacitance elements.

Further according to the present invention, the top and back surfaces can be connected to each other by use of contact holes (or through-holes) having a diameter approximately equal to the thickness of the interlayer insulating film covering the top surface, resulting in a reduction in the area of the through-holes.

Further according to the present invention, the entire gate metal can be formed on the same plane, which prevents breakage of the gate metal as well as contact between the active layer and the gate metal. In the case of a conventional semiconductor active device, particularly a field-effect transistor, the gate metal coated on the step portions of the mesa may break or the gate metal may come into contact with the active layer during the “the mesa-type device separation” process.

Explanation of reference numerals used in this specification is as follows:
1 . . . GaAs substrate
2 . . . n-InGaP etching stopper layer
3 . . . n-GaAs sub-emitter layer
4 . . . n-InGaP emitter layer
5 . . . p-GaAs base layer
6 . . . n-GaAs collector layer
7 . . . n-GaAs collector capping layer
8 . . . collector electrode
9 . . . SiO₂ film
10 . . . Au wire
11 . . . adhesive
12 . . . bonding substrate
13 . . . base electrode
14 . . . emitter electrode
15 . . . dielectric film
16 . . . emitter bump
17 . . . high-frequency signal base bump
18 . . . DC signal base bump
19 . . . collector bump
20 . . . capacitance element
23 . . . n-GaAs sub-collector layer
24 . . . n-InGaP collector layer
25 . . . p-GaAs base layer
26 . . . n-GaAs emitter layer
28 . . . emitter electrode
29 . . . emitter bump
30 . . . Au wire
33 . . . base electrode
34 . . . collector electrode
35 . . . dielectric film
36 . . . collector bump
37 . . . base bump
38 . . . emitter bump
39 . . . capacitance element
43 . . . n-GaAs sub-emitter layer
44 . . . n-InGaP emitter layer
45 . . . . p-GaAs base layer
46 . . . n-GaAs collector layer
48 . . . collector electrode
49 . . . collector bump
50 . . . Au wire
53 . . . base electrode
54 . . . emitter electrode
55 . . . dielectric film
56 . . . emitter bump
57 . . . base bump
58 . . . collector bump
59 . . . capacitance element
61 . . . GaAs substrate
62 . . . GaAs buffer layer
63 . . . undoped Al_{0.25}Ga_{0.75}As layer
64 . . . undoped GaAs layer
65 . . . undoped In_{0.25}Ga_{0.75}As active layer
66 . . . undoped GaAs layer
67 . . . undoped Al_{0.25}Ga_{0.75}As layer
68 . . . n-Al_{0.25}sGa_{0.75}As carrier supply layer
69 . . . n-Al_{0.25}Ga_{0.75}As layer
70 . . . n-GaAs capping layer
71 . . . source electrode
72 drain electrode
73 gate electrode
74 . . . transistor active region
75 . . . SiO₂ film
76 . . . adhesive
77 . . . bonding substrate
101 . . . module wire
102 . . . DC signal bump
103 . . . high-frequency signal bump
104 . . . rear wire
105 . . . capacitance element
106 . . . rear wire
107 . . . capacitance element
108 . . . collector wire
109 . . . rear wire
110 . . . rear wire
111 . . . capacitance element
112 . . . collector wire
113 . . . collector bump
114 . . . emitter bump
115 . . . MMIC chip
116 . . . passive device
121 . . . capacitance element
122 . . . capacitance element
123 . . . first-stage semiconductor device
124 . . . second-stage semiconductor device
125 . . . wire
126 . . . wire

What is claimed is:

1. A microwave integrated circuit device comprising:
a semiconductor active device that includes at least three semiconductor layers acting as an input portion, an output portion, and a ground portion, respectively, wherein at least one of said three semiconductor layers has a first conductor layer formed (thereunder) such that said first conductor layer is in Schottky or ohmic contact with said at least one of said three semiconductor layers; and
a capacitance element that includes a first capacitance electrode, a second capacitance electrode facing said first capacitance electrode, and a dielectric layer sandwiched between said first and second capacitance electrodes, wherein said first capacitance electrode is made up of at least one of said first conductor layer and a second conductor layer connected to said first conductor layer.

2. The microwave integrated circuit device as claimed in claim 1, wherein:
said semiconductor active device is a bipolar transistor; and
said three semiconductor layers constitute an emitter region, a base region, and a collector region, respectively, of said transistor.

3. The microwave integrated circuit device as claimed in claim 2, wherein:
said semiconductor active device is formed such that said emitter, base, and collector regions are disposed on a substrate in that order; and
said first capacitance electrode of said capacitance element is a conductor layer selected from the group consisting of first conductor layers in contact with said emitter, base, and collector regions, respectively, and second conductor layers connected to their respective first conductor layers.

4. The microwave integrated circuit device as claimed in claim 3, wherein:
said capacitance element includes two first capacitance electrodes; and
said two first capacitance electrodes are two different conductor layers selected from the group consisting of said first conductor layers in contact with said emitter, base, and collector regions, respectively, and said second conductor layers.

5. The microwave integrated circuit device as claimed in claim 2, wherein:
said semiconductor active device is formed such that said collector, base, and emitter regions are disposed on a module substrate in that order; and
said first capacitance electrode of said capacitance element is a conductor layer selected from the group consisting of first conductor layers in contact with said collector, base, and emitter regions, respectively, and second conductor layers connected to their respective first conductor layers.

6. The microwave integrated circuit device as claimed in claim 5, wherein:
said capacitance element includes two first capacitance electrodes; and
said two first capacitance electrodes are two different conductor layers selected from the group consisting of said first conductor layers in contact with said collector, base, and emitter regions, respectively, and said second conductor layers connected to their respective first conductor layers.

7. The microwave integrated circuit device as claimed in claim 1, wherein said capacitance element is provided between a principal surface of a module substrate and a surface of said first conductor layer or said second conductor layer, said surface being parallel to said principal surface of said module substrate.

8. The microwave integrated circuit device as claimed in claim 1, comprising a plurality of said semiconductor active devices connected in parallel to one another.

9. The microwave integrated circuit device as claimed in claim 1, comprising a plurality of said semiconductor active devices connected in parallel to one another,
wherein said capacitance element is formed in regions between said semiconductor active devices.

10. The microwave integrated circuit device as claimed in claim 1, further comprising:
a substrate for crystal growth of said semiconductor layers of said semiconductor active device;
wherein the portion of said substrate in a region in which said semiconductor active device is formed has been removed, or the portion of said substrate in a region in which said capacitance element is formed has been removed, or both.

11. A power amplifier comprising:
amplifier circuits connected to one another in a multistage fashion (or serially), each amplifier circuit including one or more semiconductor active devices connected in parallel to one another;
wherein each amplifier circuit is the microwave integrated circuit device as claimed in claim 1.

12. A power amplifier comprising:
amplifier circuits connected to one another in a multistage fashion (or serially), each amplifier circuit including one or more semiconductor active devices connected in parallel to one another;
wherein each amplifier circuit is the microwave integrated circuit device as claimed in claim 2.

13. A method for manufacturing a microwave integrated circuit device, comprising the steps of:
forming a semiconductor active device that includes three semiconductor layers acting as an input terminal, an output terminal, and a ground terminal, respectively, wherein at least one of said three terminals has a metal electrode formed right thereunder such that said metal electrode is in Schottky or ohmic contact with said at least one of said three terminals; and
forming a capacitance element that includes a first capacitance electrode, a second capacitance electrode, and a dielectric film sandwiched between said first and second capacitance electrodes, wherein said first capacitance electrode is made up of at least one of said metal electrode and a metal wire connected to said metal electrode.

14. The method as claimed in claim 13, wherein:
said semiconductor active device is a bipolar transistor; and
said step of forming said semiconductor active device includes the steps of:
sequentially forming a sub-emitter layer, an emitter layer, a base layer, and a collector layer on a semiconductor substrate; and
forming an emitter electrode, a base electrode, and a collector electrode electrically connected to said emitter, base, and collector layers, respectively, wherein said emitter electrode is disposed right under said sub-emitter layer, or said base electrode is disposed right under said base layer, or both.

15. The method as claimed in claim 13, wherein:
said semiconductor active device is a bipolar transistor; and
said step of forming said semiconductor active device includes the steps of:
sequentially forming a sub-collector layer, a collector layer, a base layer, and an emitter layer on a semiconductor substrate; and
forming a collector electrode, a base electrode, and an emitter electrode electrically connected to said collector, base, and emitter layers, respectively, wherein said collector electrode is disposed right under said sub-collector layer, or said base electrode is disposed right under said base layer, or both.

16. The method as claimed in claim 13, wherein:
said semiconductor active device is a field-effect transistor; and
said step of forming said semiconductor active device includes the steps of:
forming an active layer on a semiconductor substrate;
forming a gate electrode above said active layer; and
forming a source electrode and a drain electrode on respective sides of said gate electrode, wherein said source and drain electrodes are electrically connected to said active layer and wherein at least one of said source and drain electrodes is disposed right under said active layer.

17. The method as claimed in claim 13, further comprising the step of:
forming said capacitance element right under said metal electrode or said metal wire connected to said metal electrode.

18. The method as claimed in claim 13, further comprising the step of:
removing the semiconductor substrate entirely or at least the portions of said semiconductor substrate in regions in which said semiconductor active device and said capacitance element are formed.
